(19) United States
(12) Patent Application Publication
(10) Pub. No.: US 2019/0204916 A1
(43) Pub. Date: Jul. 4, 2019

(54) BRAINWAVE CONTROL METHOD AND DEVICE, AND DISPLAY DEVICE

(71) Applicant: BOE TECHNOLOGY GROUP CO., LTD., Beijing (CN)

(72) Inventor: Wenbo Li, Beijing (CN)

(21) Appl. No.: 16/329,143

(22) PCT Filed: Feb. 11, 2018
(86) PCT No.: PCT/CN2018/076278

§ 371 Date: Feb. 27, 2019

(30) Foreign Application Priority Data
Jun. 19, 2017 (CN) 201710463945.0

(51) Int. Cl. G06F 3/01; G09G 3/34; G09G 3/3225; G02B 26/02; G02F 1/13; H01L 27/32

(52) U.S. Cl. CPC G06F 3/015; G09G 3/3406; G09G 3/3225; G02B 26/02; G09G 2354/00; H01L 27/3232; G09G 2320/0626; G09G 2320/068; G02F 1/1323

(57) ABSTRACT

A brainwave control method is disclosed. The method includes acquiring a brain wave signal of a user. The method includes processing the brainwave signal to acquire a feature parameter of the brainwave signal (S120). If the feature parameter of the brainwave signal meets a predetermined condition, then the method includes sending a predetermined control instruction. T predetermined control instruction is configured to trigger a grating assembly of a display device to change a state thereof to adjust a viewing angle and/or brightness distribution of the display device.

The present application is based upon International Application No. PCT/CN2018/076278, filed Feb. 11, 2018, which is based upon and claims priority to Chinese patent application No. 201710463945.0, which was filed with the SIPO on Jun. 19, 2017 and is fully incorporated herein by reference as part of this application.

### TECHNICAL FIELD

The present disclosure relates to the field of display technology, and particularly to a brain wave controlling method, a brain wave controlling device and a display device.

### BACKGROUND

With the progress and development of technology, people's lives have entered the age of intelligent internet of thing (IIOT). How to make users feel more convenient and comfortable has become the first thing which should be taken into account. With the user demand as guidance, human-oriented has become a new market requirement and also promotes the generation of C2C business model. Furthermore, the customization of hardware products has also become an entry point of the current potential market.

With continuous development of display technology, display apparatuses such as television and computer as well as electronic apparatuses such as mobile phone have increasingly become necessities in people's daily lives. However, users usually have to operate the above-mentioned display apparatuses with the aid of some auxiliary devices for manipulating the display apparatuses.

With the development of human-machine interaction techniques, the conventional human-machine interaction techniques have been gradually transformed towards the direction of intelligent interaction, natural interaction and the like. The key point of human-machine interaction has also been developed from defining an interaction mode, designing an interaction semantic and the like towards paying close attention to the user's brain wave and hence uncovering the user's implicit requirements. The brain wave is formed from a summation of postsynaptic potentials synchronously generated by a large number of nerve cells during a brain activity. The brain wave records a change of electric wave during the brain activity, and is an overall reflection of electrophysiology activities of brain neurons in cerebral cortex or scalp surface. As a result, the brain wave is an important biological signal which represents the activity of human's brain.

Therefore, the related technology still has room for improvement.

It should be explained that, information disclosed in the “BACKGROUND” above is merely for enhancing an understanding of the background of the present disclosure, and hence may contain information which is not pertained to related technology well-known for those ordinary skilled in the art.

### SUMMARY

According to an aspect of the present disclosure, it provides a brain wave controlling method. The method includes acquiring a brain wave signal of a user. The method includes processing the brain wave signal to obtain a characteristic parameter of the brain wave signal. The method includes transmitting a preset control instruction upon the characteristic parameter of the brain wave signal satisfying a preset condition. The preset control instruction is configured to trigger changing a status of a grating component of a display device.

In an exemplary arrangement of the present disclosure, the characteristic parameter of the brain wave signal includes at least one of frequency and amplitude of the brain wave signal within a preset time period.

According to another aspect of the present disclosure, it provides a brain wave controlling device. The brain wave controlling device includes a signal acquiring module configured to acquire a brain wave signal of a user. The brain wave controlling device includes a signal processing module configured to process the brain wave signal to obtain a characteristic parameter of the brain wave signal. The brain wave controlling device includes an instruction transmitting module configured to transmit a preset control instruction upon the characteristic parameter of the brain wave signal satisfying a preset condition. The preset control instruction is configured to trigger changing a status of a grating component of a display device.

According to still another aspect of the present disclosure, it provides a display device. The display device includes a brain wave receiver, a display panel and a grating component. The brain wave receiver is configured to receive a preset control instruction. The preset control instruction is generated according to a brain wave signal of a user. The grating component is configured to change a status of the grating component according to the preset control instruction.

In an exemplary arrangement of the present disclosure, the grating component is further configured to adjust at least one of a viewing angle and a brightness distribution of the display panel by changing the status of the grating component of the display panel.

In an exemplary arrangement of the present disclosure, the grating component is a micro-electro-mechanical system (MEMS) grating.

In an exemplary arrangement of the present disclosure, the MEMS gating includes a movable grating and a fixed grating which are disposed opposite to each other. The status of the grating component is changed by adjusting an overlapped area between a light transmittance portion of the movable grating and a light transmittance portion of the fixed grating.

In an exemplary arrangement of the present disclosure, the brain wave receiver is disposed at a light emergent side of the display panel and is located on the display panel.

In an exemplary arrangement of the present disclosure, the display panel is a liquid crystal display (LCD) display panel, and the display device further includes a backlight component. The grating component is disposed at a light incident side of the LCD display panel. The backlight component is disposed at a side of the grating component far away from the LCD display panel.

In an exemplary arrangement of the present disclosure, the display panel is an organic light-emitting diode (OLED)/quantum dot light-emitting diode (QLED) display panel, and the grating component is integrated in the OLED/QLED display panel.

In an exemplary arrangement of the present disclosure, the OLED/QLED display panel includes an OLED/QLED light-emitting layer, a TFT driver layer and a grating layer which are disposed in sequence.

In an exemplary arrangement of the present disclosure, the display device further includes a grating driver. The grating driver is electrically connected to the brain wave receiver and the grating component.

### BRIEF DESCRIPTION OF THE DRAWINGS

The drawings herein that are incorporated in the description as a part of the present description illustrate arrangement(s) in accordance with the present disclosure and are used for explaining the principle of the present disclosure, along with the description. Apparently, the drawings described below are merely some arrangements recorded in the present disclosure, from which other drawing(s) may be derived by those ordinary skilled in the art.

FIG. 1 illustrates a flow chart of a brain wave controlling method in an exemplary arrangement of the present disclosure;

FIG. 2 illustrates a schematic diagram of a brain wave controlling device in an exemplary arrangement of the present disclosure;

FIG. 3 illustrates a schematic diagram of a display device in an exemplary arrangement of the present disclosure;

FIG. 4 illustrates a schematic diagram of an MEMS grating in an exemplary arrangement of the present disclosure;

FIG. 5 illustrates a schematic diagram illustrating changing a status of an MEMS grating in an exemplary arrangement of the present disclosure;

FIG. 6 illustrates a schematic diagram of another display device in an exemplary arrangement of the present disclosure; and

FIG. 7 illustrates a schematic diagram of still another display device in an exemplary arrangement of the present disclosure.

### DETAILED DESCRIPTION

Exemplary arrangement(s) now will be more fully described with reference to the drawings. However, the exemplary arrangement(s) may be implemented in various ways, and shall not be interpreted as being limited to the typical arrangement(s) set forth herein; the described feature(s), structure(s) or characteristic(s) may be combined in one or more arrangement in any appropriate way. In the description below, a plenty of specific details will be provided so that the arrangement(s) of the present disclosure is adequately understandable. However, those skilled in the art should be appreciated that, technical solution(s) of the present disclosure may be practiced with omitting one or more of these specific details, or other method(s), component(s), device(s), step(s) and the like may also be adopted.

It should be pointed out that, in the drawings, dimension(s) of layer(s) and area(s) may be exaggerated for more clear illustration. Furthermore, it should be appreciated that, when an element or a layer is referred to as being located “above” another element or layer, it may be directly on another element or layer, or an intermediate layer or element may be present. Moreover, it should be appreciated that, when an element or a layer is referred to as being located “below” another element or layer, it may be directly below another element or layer, or more than one intermediate layer or element may be present. Furthermore, it should also be appreciated that, when an element or a layer is referred to as being located “between” two layers or two elements, it may be the one and only layer or element between the two layers or two elements, or more than one intermediate layer or element may be present. Throughout the present disclosure, similar reference signs indicate similar components.

FIG. 1 illustrates a flow chart of a brain wave controlling method in an exemplary arrangement of the present disclosure.

As illustrated in FIG. 1, the brain wave controlling method can include the blocks as shown below.

In block S110, acquiring a brain wave signal of a user.

In an exemplary arrangement, acquiring the brain wave signal of the user can be implemented by a plurality of electrodes on a wearable apparatus and by attaching the plurality of electrodes onto one or more of a rear portion, a left portion, a right portion and a front portion of a head of the user, respectively. By way of example, acquiring the brain wave signal of the user through the wearable apparatus can refer to the related technology, which will not be particularly limited herein.

It should be explained that, the wearable apparatus in the arrangement of the present disclosure can be any wearable apparatus capable of realizing acquiring a brain wave signal, such as an intelligent helmet, an intelligent bracelet and an intelligent eyeglass, without particularly limited in the arrangement of the present disclosure.

In other arrangement(s), acquiring the brain wave signal of the user can also be implemented by a plurality of electrodes connected to a display device, which can realize acquiring the brain wave signal of the user without the aid of the wearable apparatus.

By way of example, a brain wave is an electric current generated outside cells of cerebral cortex caused by a potential difference among cell populations of the cerebral cortex during a thinking activity of the human's brain. A parameter of brain wave (e.g., a frequency or amplitude of the brain wave) is varied depending on information to be delivered by a human's brain. Thus, a display device having an information processing function can detect a brain wave of a user who is interacting with the display device, so as to determine an interaction instruction of the user.

In block S120, processing the brain wave signal to obtain a characteristic parameter of the brain wave signal.

In an exemplary arrangement, performing an analog-digital (AD) conversion to an analog brain wave signal acquired in the block above, to obtain a digital brain wave signal; and extracting a characteristic parameter from the digital brain wave signal by using an algorithm analysis. The extracting algorithm can refer to the related technology, which will not be described in details herein.

In an exemplary arrangement, the characteristic parameter of the brain wave signal includes at least one of a frequency and amplitude of the brain wave signal within a preset time period.

In the arrangement of the present disclosure, the user can control at least one of a brightness distribution and a viewing angle of the display device when displaying in such a manner that the user focuses on controlling for a certain time period, for example, calculating once about every 5 seconds; in such case, acquiring an effective characteristic peak of the brain wave for one time, so as to obtain an effective data of “1” and to convey an effective command of “one time” which stimulates a status of the display device for one time.

It should be explained that, the above-mentioned preset time period can be, for example, 5 seconds, for preventing from spurious triggering. A value of the preset time period can be configured by the user himself according to demands, without particularly limited in the arrangement of the present disclosure.

In a practical application, because a brain wave signal is likely to be interfered by other noise signal(s) including EOG interference, EMG interference, ECG interference, power line interference, electromagnetic interference and the like during the acquiring process, it has to be pre-processed to remove artifact(s) doped in the brain wave signal, so as to extract an effective brain wave signal from the acquired brain wave signal. The power line interference and the electromagnetic interference always are occurred in a high-frequency band, thus it's possible to filter out a frequency band which is likely to be interfered, by way of band-pass filtering or low-pass filtering, and to retain only the brain wave signal within an effective frequency band. As a result, the extraction of the effective brain wave signal can be implemented by the following: performing a filtering process to the acquired brain wave signal by band-pass filtering or low-pass filtering according to a preset interference frequency band, and then extracting an effective brain wave signal of the user from the signal having been subjected to the filtering process. By way of example, the above-mentioned block of extracting an effective brain wave signal from the signal having been subjected to the filtering process can include: extracting an effective brain wave signal of the user from the signal having been subjected to the filtering process by using a principal component analysis (PCA) or an independent component analysis (ICA).

In block S130, transmitting a preset control instruction upon the characteristic parameter of the brain wave signal satisfying a preset condition.

The preset control instruction is for triggering changing a status of the grating component of the display device, so as to adjust at least one of a viewing angle and a brightness distribution of the display device.

Upon the characteristic parameter of the current brain wave signal satisfying a preset condition, determining a preset control instruction corresponding to the current brain wave signal according to the current brain wave signal. For example, determining a characteristic parameter of the current brain wave signal; matching the characteristic parameter of the current brain wave signal with a characteristic parameter of a preset brain wave signal in a brain wave data set; the brain wave data set is pre-stored with a corresponding relation between the characteristic parameter of the preset brain wave signal and the preset control instruction; upon the characteristic parameter of the current brain wave signal matching with the characteristic parameter of the preset brain wave signal, obtaining the preset control instruction corresponding to the matched, preset brain wave signal.

By way of example, the characteristic parameter of the brain wave signal can be at least one of a frequency and amplitude of the brain wave signal. The preset control instruction can be an instruction corresponding to at least one of operating the brightness distribution and the viewing angle of the display device when displaying.

Description will be given with reference to the case where the characteristic parameter of the brain wave signal is frequency, by way of example.

When obtaining a brain wave of a user who is being gazing, determining whether a frequency of the current brain wave satisfies a preset condition; if satisfied, determining a preset control instruction corresponding to the current brain wave according to the current brain wave; otherwise, doing nothing or reporting an error.

In an arrangement of the present disclosure, correspondingly controlling the status of the grating component of the display device according to the preset control instruction. For example, by controlling to focus through the brain for one time, the MEMS grating can be stimulated for one time so as to change its status.

The preset condition in the block S130 is a preset condition relating to the characteristic parameter of the brain wave signal, and the preset condition is varied depending on the characteristic parameter of the brain wave signal.

By way of example, if the characteristic parameter above is the frequency of the brain wave signal, the preset condition is a frequency threshold.

Further, by way of example, a user who is watching image content usually has a degree of concentration lower than that of the user when operating at least one of the brightness distribution and the viewing angle of the display device as mentioned above. As a result, the user who is watching the image content can transmit α brain wave (8-12 Hz) as mentioned above, while the user who needs to operate at least one of the brightness distribution and the viewing angle of the display device can transmit β brain wave (12-30 Hz) as mentioned above. The above-mentioned frequency threshold can be 12 Hz. That is to say, a frequency of the current brain wave signal smaller than 12 Hz indicates that the user is only watching the image content without any intention of operating at least one of the brightness distribution and the viewing angle of the display device. While a frequency of the current brain wave greater than 12 Hz indicates that the user needs to operate at least one of the brightness distribution and the viewing angle of the display device. Under such circumstance, a preset control instruction corresponding to the current brain wave signal indicates operating at least one of the brightness distribution and the viewing angle of the display device, which needs to change the status of the grating component of the display device. When the frequency of the current brain wave signal as acquired is smaller than the above-mentioned frequency threshold (12 Hz), no operation will be performed to the grating component of the display device.

When the above-mentioned characteristic parameter is the frequency and amplitude of the brain wave signal, the preset condition includes a frequency threshold and whether a waveform peak of the current brain wave signal is suddenly changed during the acquiring stage.

It can be seen from the above that, the wearable apparatus or the display device can be pre-stored with some characteristic parameters corresponding to the preset control instruction. For example, the β brain wave having a frequency of 12-30 Hz corresponds to a control instruction allowing the status of the grating component of the display device to be correspondingly changed. The arrangement of the present disclosure can further include a plurality of preset control instructions. The preset condition is whether the current brain wave signal is matched with a pre-stored, preset brain wave signal.

It should be explained that, the characteristic parameter of the current brain wave signal matching with the characteristic parameter of the preset brain wave signal refers to that, a difference between the characteristic parameter of the current brain wave signal and the characteristic parameter of the preset brain wave signal is within a tolerable error range. The error can be determined by a precision of the wearable apparatus or the display device, without limited in the present disclosure.

It should be explained that, the preset brain wave signal is a brain wave signal pre-stored in the wearable apparatus before leaving the factory or during an initialization stage.

By way of example, it's possible to acquire different preset brain wave signals transmitted by a user who stays awake and focused, under different thinking activity conditions, before the wearable apparatus leaving the factory or during an initialization stage. For example, the user who stays awake and focused will transmit β brain wave with a frequency of 12-30 Hz.

Of course, the above-mentioned frequency of the preset brain wave signal corresponding to the preset control instruction is merely described by way of example.

In this way, by pre-storing a brain wave data set including a corresponding relation between the characteristic parameter of the preset brain wave signal and the preset control instruction, all the brain waves having a frequency of 12-30 Hz will be corresponding to the preset control instruction.

On this basis, before acquiring the above-mentioned current brain wave signal, the method can further include the followings.

First of all, the method can include determining a characteristic parameter of a preset brain wave signal and storing the same.

Secondly, the method can include establishing a brain wave data set including a corresponding relation between a characteristic parameter of the preset brain wave signal and a preset control instruction, that is, establishing a mapping relation between the characteristic parameter of the preset brain wave signal and the preset control instruction. In this way, when the current brain wave signal is matched with the characteristic parameter of the preset brain wave signal, it enables invoking the preset control instruction having a mapping relation with the preset brain wave signal through the preset brain wave signal by way of addressing access.

An arrangement of the present disclosure provides a brain wave controlling method, including: acquiring a current brain wave signal of a user; subsequently, determining a preset control instruction corresponding to the current brain wave signal according to the current brain wave signal when a characteristic parameter of the current brain wave signal satisfies a preset condition; finally, controlling a status of a grating component of a display device according to the preset control instruction. In this way, it's possible to determine whether the user needs to perform an operation of controlling at least one of a brightness distribution and a viewing angle of the display device when displaying as mentioned above through the brain wave. As a result, the above-mentioned controlling process has no need of manual operation, so as to improve the operational convenience of the user when using the display device.

The brain wave controlling method in some arrangements of the present disclosure generates a preset control instruction through a brain wave signal, and triggers changing a status of a grating component of a display device according to the preset control instruction, so as to adjust at least one of a viewing angle and a brightness distribution of the display device when displaying, through the brain wave signal of the user.

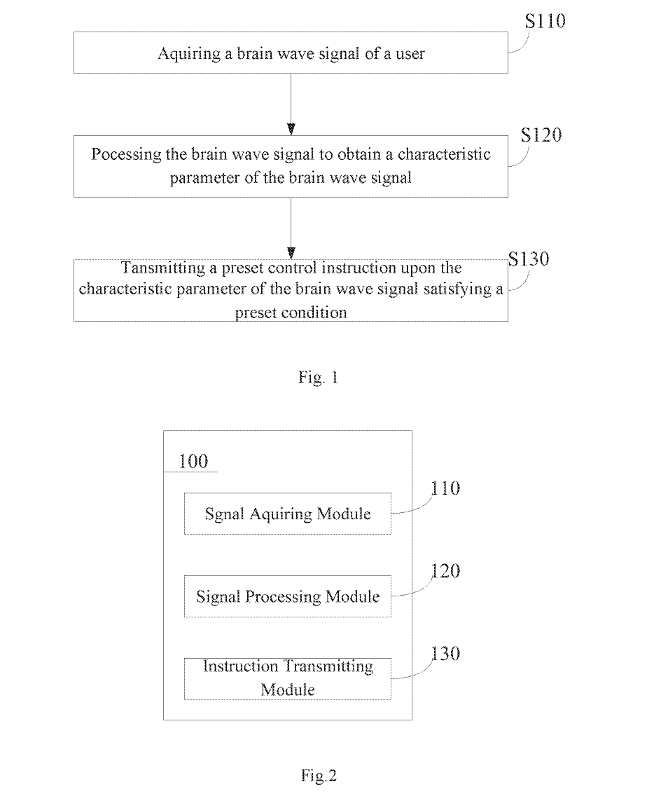

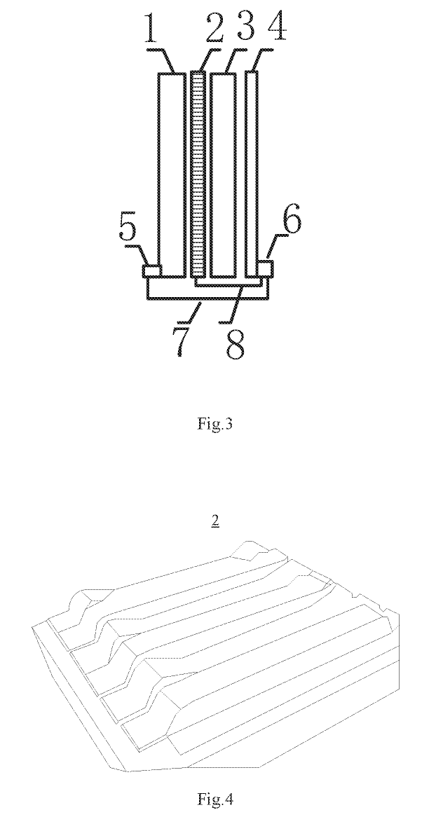

FIG. 2 illustrates a schematic diagram of a brain wave controlling device in an arrangement of the present disclosure.

As illustrated in FIG. 2, the brain wave controlling device 100 can include a signal acquiring module 110, a signal processing module 120 and an instruction transmitting module 130.

The signal acquiring module 110 can be configured to acquire a brain wave signal of a user.

The signal processing module 120 can be configured to process the brain wave signal to obtain a characteristic parameter of the brain wave signal.

In an exemplary arrangement, the characteristic parameter of the brain wave signal includes at least one of frequency and amplitude of the brain wave signal within a preset time period.

The instruction transmitting module 130 can be configured to transmit a preset control instruction when the characteristic parameter of the brain wave signal satisfies a preset condition.

The preset control instruction is configured to trigger changing a status of a grating component of a display device, so as to adjust at least one of a viewing angle and a brightness distribution of the display device.

Implementing modes of the modules in the above-mentioned brain wave controlling device can refer to the arrangements of the above-mentioned brain wave controlling method, without repeating herein.

In an arrangement, an implementing mode of the present disclosure further provides a display device, and the display device can include a brain wave receiver, a display panel and a grating component. The brain wave receiver is configured to receive a preset control instruction, and the present control instruction is generated according to a brain wave signal of a user; the grating component is configured to change its status according to the preset control instruction, so as to adjust at least one of a viewing angle and a brightness distribution of the display panel.

In an exemplary arrangement, the grating component is a micro-electro-mechanical system (MEMS) optical grating.

The MEMS grating possesses incomparable improvements in terms of power consumption. A transmittance of light emitted from a backlight source can be controlled by an MEMS light valve, so as to realize controlling at least one of a brightness distribution and a viewing angle in an image display.

In an exemplary arrangement, the MEMS grating can include a movable grating and a fixed grating which are disposed opposite to each other. The light has to pass through a light transmittance portion of the fixed grating to reach a reflective layer, and then emits after a reflection of the reflective layer. An amount of the light reaching the reflective layer can be adjusted by adjusting an overlapped area between a light transmittance portion of the movable grating and the light transmittance portion of the fixed grating, so as to finally realize the image display.

The display device provided by the arrangement of the present disclosure is a display device controllable by a brain. By directly controlling the MEMS grating through a brain wave signal, at least one of the viewing angle and brightness distribution when displaying can be automatically adjusted.

In an exemplary arrangement, the brain wave receiver can be disposed at a light emergent side of the display panel and is located on the display panel. The brain wave receiver is configured to receive a preset control instruction; as a result, the brain wave receiver disposed at the light emergent side of the display panel is more beneficial for receiving signal. By way of example, the brain wave receiver can be disposed in a non-display region of the display panel. However, the arrangement of the present disclosure is not limited thereto, and the brain wave receiver can be disposed at any position of the display device as long as it can receive a signal indicative of transmitting the preset control instruction. For example, the brain wave receiver can also be integrated in the display panel.

In an exemplary arrangement, the display panel can be a LCD display panel. Hereinafter, a structure of a LCD display panel used as the display panel will be described by way of example with reference to FIG. 3.

FIG. 3 illustrates a schematic diagram of a display device in an exemplary arrangement of the present disclosure.

As illustrated in FIG. 3, a reference numeral “1” indicates a LCD display panel, a reference numeral “2” indicates an MEMS grating, a reference numeral “3” indicates a backlight component, a reference numeral “4” indicates a driver circuit, and a reference numeral “5” indicates a brain wave receiver.

In the arrangement illustrated in FIG. 3, the MEMS grating 2 is disposed at a light incident side of the LCD display panel 1. The backlight component 3 is disposed at a side of the MEMS grating 2 far away from the LCD display panel 1.

Still referring to FIG. 3, the display device can further include a grating driver 6 electrically connected to the brain wave receiver 5 and the MEMS grating 2 through signal transmission lines 7 and 8, respectively.

When receiving the preset control instruction as transmitted, the brain wave receiver 5 controls the grating driver 6, according to the preset control instruction, to drive the MEMS grating 2, so as to change a status of the MEMS grating 2, and hence to change at least one of a viewing angle and a brightness of the LCD display panel.

Additionally, in other exemplary arrangement(s) of the present disclosure, the display device can further include other component(s). Therefore, technical solution(s) in which more structure(s) is/are added is/are also within the protection scope of the present disclosure.

FIG. 4 illustrates a schematic diagram of the MEMS grating 2 of FIG. 3 in an exemplary arrangement of the present disclosure. By way of example, a structure and a working principle of the MEMS grating can refer to related technology, without particularly described herein.

FIG. 5 illustrates a schematic diagram of changing a status of the MEMS grating in an exemplary arrangement of the present disclosure.

As illustrated in FIG. 5, a reference numeral “3” indicates a light source light beam emitted from the backlight component, a reference numeral “2” indicates an MEMS grating, and a reference numeral “1” indicates a LCD display panel. The left portion of FIG. 5 illustrates a status of the MEMS grating 2 when no preset control instruction is received, and the right portion of FIG. 5 illustrates a status of the MEMS grating 2 when the preset control instruction is received. As it can be seen from FIG. 5, by controlling a status of the MEMS grating 2, a direction, an angle and a transmittance of the light exiting the display device can be changed, so as to change at least one of the viewing angle and the brightness distribution when displaying.

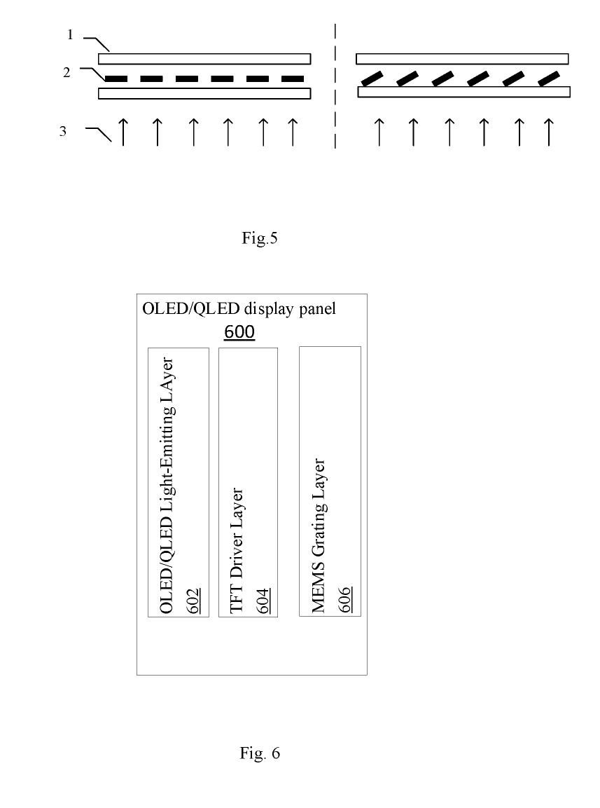

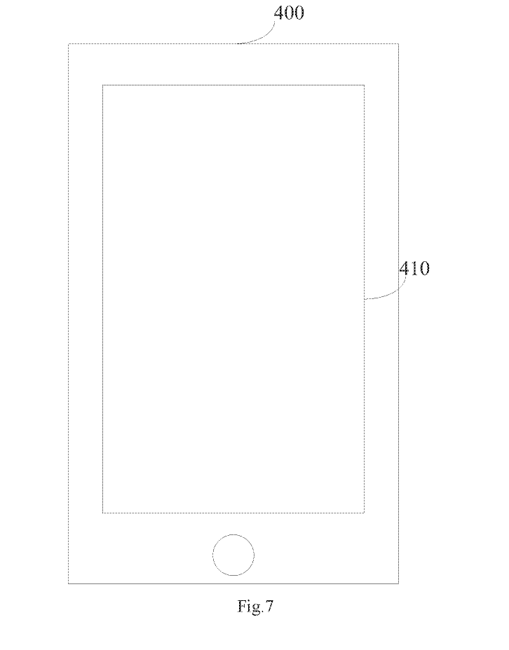

In an exemplary arrangement, the display panel can be an OLED/QLED display panel. Hereinafter, a structure of the display panel in the case of OLED/QLED display panel will be described with reference to FIG. 6 by way of example.

FIG. 6 illustrates a schematic diagram of another display device in an exemplary arrangement of the present disclosure.

As illustrated in FIG. 6, the display panel 600 is an OLED/QLED display panel, and the grating component can be integrated in the OLED/QLED display panel.

In the arrangement of the present disclosure, description will be given with reference to the case where the OLED/QLED display panel is of bottom emission type by way of example. As illustrated in FIG. 6, the OLED/QLED display panel 600 can include an OLED/QLED light-emitting layer 602, a thin film transistor (TFT) driver layer 604 and a grating layer 606 which are disposed in sequence. The grating layer is provided with an MEMS grating. In this way, light emitted from the OLED/QLED light-emitting layer, firstly, passes through the TFT driver layer, and then through the MEMS grating. As a result, a transmittance/direction/angle of the light that is emitted from the OLED/QLED light-emitting layer and finally exits the QLED/QLED display panel can be changed by changing the preset control instruction, so as to change at least one of the viewing angle and the brightness distribution when displaying.

In an exemplary arrangement, the OLED/QLED display panel can further include a packaging layer. The packaging layer can be located above the OLED/QLED light-emitting layer, for example, at a left side of the OLED/QLED light-emitting layer as illustrated in the arrangement of FIG. 6.

FIG. 7 illustrates a schematic diagram of another display device in an exemplary arrangement of the present disclosure.

In an arrangement, as illustrated in FIG. 7, the implementing mode of the present disclosure further provides a display device 400 including the brain wave receiver in the foregoing arrangement(s), a display panel 410 and a grating component.

The display device 400 can be any product or component having a display function such as a display panel, a mobile phone, a tablet computer, a television, a notebook computer, a digital photo frame and a navigation device.

Referring to FIG. 7, the display panel 410 can be a flat display panel, for example, a plasma panel, an organic light-emitting diode (OLED)/quantum dot light-emitting diode (QLED) panel, or a thin film transistor liquid crystal display (TFT LCD) panel.

In an exemplary arrangement, the display device 400 can be a LCD display device, including an array substrate and a color filter (CF) substrate disposed opposite to the array substrate. The array substrate can be a TFT-LCD array substrate. In the application, the CF substrate can also be replaced by a transparent substrate on which a color filter is disposed.

The display device can also be a box shaped OLED display device including an opposed substrate disposed opposite to the above-mentioned array substrate, and an organic light-emitting material layer disposed between the array substrate and the opposed substrate.

The display device provided by the present disclosure includes the above-mentioned brain wave receiver, display panel and grating component, and hence can solve the same technical problem and achieve the same technical effect, without repeating herein separately.

By considering the specification and practicing the disclosure described herein, other implementing mode(s) may be easily conceivable for those skilled in the art. The present disclosure is intended to cover any variation, purpose or adaptive modification of the present disclosure which is in accordance with the generic principle of the present disclosure and to include common knowledge or conventional technical measures in the technical field to which the present disclosure pertains. The specification and the arrangement(s) are merely deemed as exemplary, and the true scope and spirit of the present disclosure are indicated by the appended claims.

1. A display device, comprising a brain wave receiver, a display panel and a grating component, wherein
the brain wave receiver is configured to receive a preset control instruction, wherein the preset control instruction is generated according to a brain wave signal of a user; and
the grating component is configured to change a status of the grating component according to the preset control instruction.

2. The display device according to claim 1, wherein the grating component is further configured to adjust at least one of a viewing angle and a brightness distribution of the display panel by changing the status of the grating component of the display panel.

3. The display device according to claim 1, wherein the grating component is a micro-electro-mechanical system (MEMS) grating.

4. The display device according to claim 3, wherein the MEMS gating includes a movable grating and a fixed grating which are disposed opposite to each other, and wherein the status of the grating component is changed by adjusting an overlapped area between a light transmittance portion of the movable grating and a light transmittance portion of the fixed grating.

5. The display device according to claim 1, wherein the brain wave receiver is disposed at a light emergent side of the display panel.

6. The display device according to claim 3, wherein the display panel is a liquid crystal display (LCD) display panel, and the display device further comprises a backlight component, wherein
the grating component is disposed at a light incident side of the LCD display panel; and
the backlight component is disposed at a side of the grating component far away from the LCD display panel.

7. The display device according to claim 1, wherein the display panel is an organic light-emitting diode/quantum light-emitting diode (OLED/QLED) display panel, and the grating component is integrated in the OLED/QLED display panel.

8. The display device according to claim 7, wherein the OLED/QLED display panel comprises an OLED/QLED light-emitting layer, a thin film transistor (TFT) driver layer and a grating layer which are disposed in sequence.

9. The display device according to claim 1, further comprising a grating driver, the grating driver is electrically connected to the brain wave receiver and the grating component.

10. A brain wave controlling method, comprising:
acquiring a brain wave signal of a user;
processing the brain wave signal to obtain a characteristic parameter of the brain wave signal;
transmitting a preset control instruction upon the characteristic parameter of the brain wave signal satisfying a preset condition, to trigger changing a status of a grating component of a display device.

11. The method according to claim 10, further comprising adjusting at least one of a viewing angle and a brightness distribution of the display device by changing the status of the grating component of the display device.

12. The method according to claim 10, wherein the grating component is a micro-electro-mechanical system (MEMS) grating.

13. The method according to claim 12, wherein the MEMS gating includes a movable grating and a fixed grating which are disposed opposite to each other, and wherein changing the status of the grating component includes: adjusting an overlapped area between a light transmittance portion of the movable grating and a light transmittance portion of the fixed grating.

14. The brain wave controlling method according to claim 10, wherein the characteristic parameter of the brain wave signal comprises at least one of frequency and amplitude of the brain wave signal within a preset time period.

15. A brain wave controlling device, comprising:
a signal acquiring module configured to acquire a brain wave signal of a user;
a signal processing module configured to process the brain wave signal to obtain a characteristic parameter of the brain wave signal; and
an instruction transmitting module configured to transmit a preset control instruction upon the characteristic parameter of the brain wave signal satisfying a preset condition, wherein
the preset control instruction is configured to trigger changing a status of a grating component of a display device.

16. The display device according to claim 15, wherein the preset control instruction is further configured to adjust at least one of a viewing angle and a brightness distribution of the display panel by changing the status of the grating component of the display device.

17. The display device according to claim 15, wherein the grating component is a micro-electro-mechanical system (MEMS) grating.

18. The display device according to claim 17, wherein the MEMS gating includes a movable grating and a fixed grating which are disposed opposite to each other, and wherein the status of the grating component is changed by adjusting an overlapped area between a light transmittance portion of the movable grating and a light transmittance portion of the fixed grating.

19. The brain wave controlling device according to claim 15, wherein the characteristic parameter of the brain wave signal comprises at least one of frequency and amplitude of the brain wave signal within a preset time period.
